(19) United States
(12) Patent Application Publication
(10) Pub. No.: US 2008/0049491 A1
(43) Pub. Date: Feb. 28, 2008

(54) Electromechanical non-volatile memory device and method of manufacturing the same

(75) Inventor: Jin-Jun Park, Seoul (KR)

Correspondence Address: MILLS & ONELLO LLP, ELEVEN BEACON STREET, SUITE 605, BOSTON, MA, 02108, US

(73) Assignee: Samsung Electronics, Co., Ltd., Suwon-si (KR)

(21) Appl. No.: 11/893,058

(22) Filed: Aug. 14, 2007

(30) Foreign Application Priority Data
Aug. 22, 2006 (KR) 10-2006-0079415

(51) Int. Cl. G11C 11/50; H01L 21/4763

(52) U.S. Cl. 365/164; 438/52; 257/E21.495

(57) ABSTRACT

In a memory device and a method of manufacturing the memory device, the memory device includes first and second electrode patterns formed on a substrate. An insulating layer pattern and a third electrode pattern are successively formed on the substrate. The third electrode pattern extends to be apart from upper faces of the first and second electrode patterns by a first distance. A fourth electrode pattern extending from a lower portion of the third electrode to inside an opening defined between the first and second electrode patterns is formed to be apart from the first and second electrode patterns, the insulating layer pattern and the substrate. The fourth electrode pattern is formed toward the substrate and includes a rounded end portion.

### CROSS-REFERENCE TO RELATED APPLICATIONS

This application claims priority under 35 USC § 119 to Korean Patent Application No. 10-2006-0079415 filed on Aug. 22, 2006, the contents of which are herein incorporated by reference in their entireties.

### BACKGROUND OF THE INVENTION

1. Field of the Invention

The present invention relates to an electromechanical non-volatile memory device and a method of manufacturing the electromechanical non-volatile memory device. More particularly, the present invention relates to an electromechanical non-volatile memory device capable of electromechanically reading or writing data by using an elasticity dependent on a potential difference and a method of manufacturing the electromechanical non-volatile memory device.

2. Description of the Related Art

As the field of information technology (IT) has rapidly developed, next generation semiconductor memory devices for manufacturing a portable information communication system and a device for wirelessly processing mass data are required to have superior characteristics, such as a high speed, a mass storage capacity, a low power consumption, and so on.

The next generation semiconductor memory devices need to have a low power consumption, as well as characteristics such as a non-volatility of conventionally used flash memory device, a high operation speed of a static random access memory (SRAM) device, a high integration degree of a dynamic random access memory (DRAM) device, etc. Examples of the next generation semiconductor memory device are a ferroelectric random access memory (FRAM) device, a magnetic random access memory (MRAM) device, a phase-change random access memory (PRAM) device, etc. The FRAM device, the MRAM device, and the PRAM device operate with a relatively low voltage. In addition, the next generation semiconductor device can have superior characteristics of writing/reading the data relatively to the conventional memory device such as ROM, PROM, EPROM, EEPROM, DRAM, SRAM devices, etc.

The MRAM device uses a magnetic characteristic. The FRAM device includes a cell formed using a ferromagnetic region. The MRAM device, the FRAM device, etc., are provided as a magneto-resistance memory device having a non-isotropic magneto-resistance or a giant magneto-resistance of a ferromagnetic material. Thus, the cells have characteristics such as a high resistance, a low density, etc.

In addition, the PRAM device stores the data by using structural phase-change generated at a thin layer formed from an alloy including selenium, telluric, etc. A crystal state and an amorphous state of the alloy are stably maintained so that the alloy can achieve a switch having bi-stability. The PRAM device can be used as a non-volatile memory cell. However, an operation speed of the PRAM device is slow. In addition, processes for manufacturing the PRAM device are complex. A reliability of the PRAM device is not satisfactory.

Recently, wires on the order of nanometers are used in a semiconductor field. A memory device used as a non-volatile memory cell by electromechanically moving the wires is introduced. Hereinafter, the above memory device is referred to as an electromechanical non-volatile memory device. In the electromechanical non-volatile memory device, the wires move to make contact with an upper electrode pattern or a lower electrode pattern in response to electric signal. The wires have a structure capable of maintaining the above contact state.

For example, the electromechanical non-volatile memory device is disclosed in U.S. Pat. No. 6,924,538 and U.S. Pat. No. 5,706,423, etc.

However, in the electromechanical non-volatile memory device disclosed in U.S. Pat. No. 6,924,538, an upper portion and a lower portion of wire are fixed by an insulation pattern, so that the wire is attacked and damaged when the data is repetitively read. In addition, when the electromechanical non-volatile memory device disclosed in U.S. Pat. No. 5,706,423 is formed in array, the wires extending in substantial linear shapes can repeatedly and alternately make vertical contact with upper and lower electrodes. Thus, a durability of the memory device is relatively low. In addition, the reliability of the conventional electromechanical non-volatile memory device can be deteriorated.

### SUMMARY OF THE INVENTION

In accordance with the present invention there is provided an electromechanical non-volatile memory device having a relatively high reliability and a superior operation characteristic.

In accordance with the present invention there is provided a method of manufacturing the electromechanical non-volatile memory device.

In accordance with an aspect of the present invention, the electromechanical non-volatile memory device includes a supporting substrate, a first electrode pattern, a second electrode pattern, an insulating layer pattern, a third electrode pattern, and a fourth electrode pattern. The supporting substrate includes an upper face having an insulating property. The first and second electrode patterns are formed on the supporting substrate. The first and second electrode patterns have opposing faces. The insulating layer pattern is formed on the supporting substrate. The insulating layer pattern makes contact with rear faces of the first and second electrode patterns. The insulating layer pattern and the first and second electrode patterns form an opening between the first and second electrode patterns. The third electrode pattern is formed on the insulating layer pattern. The third electrode pattern is supported on the insulating layer pattern. The third electrode pattern has a portion that extends to be spaced apart from upper faces of the first and second electrode patterns. The fourth electrode pattern extends from a bottom face of the third electrode pattern to an inside of the opening. The fourth electrode pattern is spaced apart from the first electrode pattern, the second electrode pattern, the insulating layer and the supporting substrate. The fourth electrode pattern includes a conductive material having an elasticity depending on a potential difference. The fourth electrode pattern has a rounded end portion toward the supporting substrate. Sidewalls of the rounded end portion are convex.

The first and second electrode patterns can include a same conductive material.

A portion of the third electrode pattern formed on an upper face of the insulating layer pattern can have a first thickness and a portion of the third electrode pattern formed over the opening between the first and second electrodes can have a second thickness thinner than the first thickness.

The electromechanical non-volatile memory device can further include a structure including an oxide layer pattern, an electric charge trapping layer pattern in which an electric charge is trapped, and a dielectric layer pattern. The structure can be located between the first electrode pattern and the supporting substrate and between the second electrode pattern and the supporting substrate.

In the above, the rounded end portion of the fourth electrode pattern can be disposed proximate to the dielectric layer pattern of the structure.

The fourth electrode pattern can include one of a first metal material including titanium, a second metal material including aluminum, or a third metal material including the first and second metal materials.

The third and fourth electrode patterns can include a substantially same conductive material.

The fourth electrode pattern can be configured to make contact with at least one sidewall of the first and second electrode patterns in response to a potential difference between the fourth electrode pattern and at least one of the first and second electrode patterns.

In accordance with another aspect of the present invention, there is provided a method of manufacturing an electromechanical non-volatile memory device. In the method, a preliminary electrode pattern is formed on a supporting substrate. An insulating layer pattern making contact with a rear face of the preliminary electrode pattern is formed on the supporting substrate. The preliminary electrode pattern is partially etched to transform the preliminary electrode pattern into first and second electrode patterns having opposing faces. Here a first opening is formed between the first and second electrode patterns. A preliminary sacrificial layer pattern is formed on sidewalls of the first opening, a bottom face of the first opening, and upper faces of the first and second electrode patterns to form a second opening defined by the preliminary sacrificial layer pattern. An etch stop layer is formed on the preliminary sacrificial layer pattern formed on the sidewalls of the first opening. A portion of the preliminary sacrificial layer pattern located on the bottom face of the first opening is isotropically etched so that a bottom face of the second opening can have a rounded shape. The etch stop layer is removed. An electrode material is deposited on the insulating layer pattern and the preliminary sacrificial layer pattern to fill up the second opening. The electrode material and the preliminary sacrificial layer are partially removed to form a third electrode pattern and a preliminary fourth electrode pattern. The third electrode pattern is supported on the insulating layer pattern. The third electrode pattern has a portion that extends such that the third electrode pattern is spaced apart from upper faces of the first and second electrode patterns by a first distance. The preliminary fourth electrode pattern extends from a lower face of the extending portion of the third electrode pattern to an inside of the second opening. The sacrificial layer pattern is removed to form the fourth electrode pattern extending from the face of the extending portion of the third electrode pattern to an inside of the first opening. The fourth electrode pattern is spaced apart from the first electrode pattern, the second electrode pattern, the insulating layer pattern, and the supporting substrate. The fourth electrode pattern has a rounded end portion having convex sidewalls. The fourth electrode pattern includes a conductive material having an elasticity depending on a potential difference.

A structure including an oxide layer pattern, an electric charge trapping layer pattern and a dielectric layer pattern can be further formed under the preliminary electrode pattern.

Forming the first electrode pattern and the second electrode pattern can comprises: forming a mask pattern on the preliminary electrode pattern, the mask pattern having a linear shape extending in a first direction; and etching the preliminary electrode pattern by using the mask pattern as an etching mask.

In the above case, the method can further comprise forming a spacer on a sidewall of the mask pattern after the mask pattern is formed.

The preliminary sacrificial layer pattern can be formed to a thickness thinner than half of an inner width of the first opening.

The method can include removing the sacrificial layer pattern by an isotropic etching process.

The fourth electrode pattern can include one of a first metal material including titanium, a second metal material including aluminum, or a third metal material including the first and second metal materials.

In accordance with another aspect of the present invention, there is provided an electromechanical non-volatile memory device. The device comprises: a supporting substrate including an upper face having an insulating property; first and second electrode patterns formed on the supporting substrate, the first and second electrode patterns having opposing faces; and an insulating layer pattern formed on the supporting substrate, the insulating layer pattern making contact with rear faces of the first and second electrode patterns, the insulating layer pattern and the first and second electrode patterns forming an opening between the first and second electrode patterns. The device also includes a third electrode pattern formed on the insulating layer pattern, the third electrode pattern supported on the insulating layer pattern, the third electrode pattern having a portion extending to be spaced apart from upper faces of the first and second electrode patterns. A portion of the third electrode pattern formed on an upper face of the insulating layer pattern has a first thickness and a portion of the third electrode pattern formed over the opening between the first and second electrodes has a second thickness thinner than the first thickness. And the device includes a fourth electrode pattern extending from a bottom face of the extending portion of the third electrode pattern to an inside of the opening, the fourth electrode pattern being spaced apart from the first electrode pattern, the second electrode pattern, the insulating layer, and the supporting substrate, the fourth electrode pattern including a conductive material having an elasticity depending on a potential difference, the fourth electrode pattern having a rounded end portion toward the supporting substrate, sidewalls of the rounded end portion having a convex shape. The fourth electrode pattern is configured to make contact with at least one sidewall of the first and second electrode patterns in response to a potential difference between the fourth electrode pattern and at least one of the first and second electrode patterns.

The electromechanical non-volatile memory device can further comprise a structure including an oxide layer pattern, an electric charge trapping layer pattern in which an electric charge is trapped, and a dielectric layer pattern, the structure being located between the first electrode pattern and the supporting substrate and between the second electrode pattern and the supporting substrate.

In the above case, the bottom face of the second opening having the rounded shape can be provided such that the bottom face of the second opening is disposed proximate to the dielectric layer pattern of the structure.

According to aspects of the present invention, the electromechanical non-volatile memory device records data by shifting the fourth electrode pattern in right and left directions. The fourth electrode pattern is spaced apart from the supporting substrate so that the fourth electrode pattern can be effectively shifted toward the first electrode pattern or the second electrode pattern in response to a potential difference between the fourth and first electrode patterns or between the fourth and second electrode patterns. Thus, an operation characteristic and a reliability of the electromechanical non-volatile memory device can be improved.

Additionally, the fourth electrode pattern can be downwardly protruded toward the supporting substrate. The fourth electrode pattern has a rounded end portion having convex sidewalls so that the fourth electrode pattern can be easily shifted toward the first electrode pattern or the second electrode pattern by a relatively small force such as a potential difference.

Furthermore, the third electrode pattern connected to the fourth electrode pattern need not be shifted by the potential difference during a writing operation and/or a reading operation. Thus, the operation of the electromechanical non-volatile memory device can be stable and reliable.

### BRIEF DESCRIPTION OF THE DRAWINGS

The above and other features and advantages of the present invention will become readily apparent by reference to the following detailed description when considered in conjunction with the accompanying drawings, wherein:

FIG. 1 is a perspective view illustrating an embodiment of an electromechanical non-volatile memory device in accordance with an aspect of the present invention;

FIGS. 2 and 3 are perspective views illustrating data storage states of the electromechanical non-volatile memory device in FIG. 1;

FIGS. 4 to 15 are perspective views illustrating an embodiment of a method of manufacturing the electromechanical non-volatile memory device in FIG. 1;

FIG. 16 is a perspective view illustrating an embodiment of an electromechanical non-volatile memory device in accordance with another aspect of the present invention; and

FIGS. 17 to 23 are perspective views illustrating a method of manufacturing the electromechanical non-volatile memory device in FIG. 16.

### DESCRIPTION OF THE EMBODIMENTS

Hereinafter, aspects of the present invention will be described by explaining illustrative embodiments in accordance therewith, with reference to the attached drawings. While describing these embodiments, detailed descriptions of well-known items, functions, or configurations are typically omitted for conciseness.

The present invention can, however, be embodied in many different forms and should not be construed as limited to the example embodiments set forth herein. In the drawings, the sizes and relative sizes of layers and regions can be exaggerated for clarity.

It will be understood that when an element or layer is referred to as being “on” or “connected to” another element or layer, it can be directly on, connected or coupled to the other element or layer or intervening elements or layers can be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, third etc. can be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device can be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments in accordance with the present invention are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments, and the present invention, should not be construed as limited to the particular shapes of regions illustrated herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation can result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

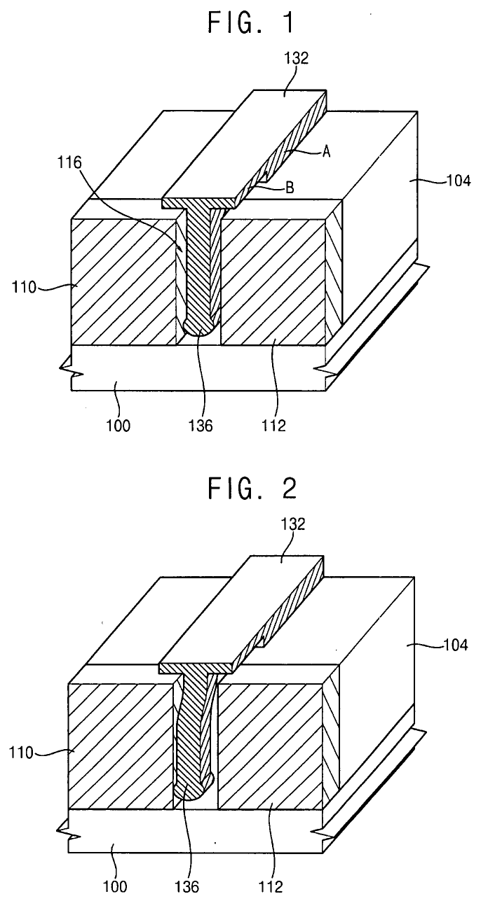

FIG. 1 is a perspective view illustrating an electromechanical non-volatile memory device in accordance with an example embodiment of the present invention.

Referring to FIG. 1, a supporting substrate 100 can be provided. An upper face of the supporting substrate 100 can have an insulating property. Unlike a conventional memory device, the supporting substrate can not include a semiconductor material such as silicon. As one example, the entire supporting substrate 100 can include a material having the insulating property. As another example, the supporting substrate 100 can include a first portion having a plate shape and a second portion formed on the first portion. The first portion can include a metal or the semiconductor material. The second portion can be formed by depositing an insulating material on the first portion.

A first electrode pattern 110 and a second electrode pattern 112 can be formed on the supporting substrate 100 such that the first and second electrode patterns 110 and 112 can face each other.

Thicknesses of the first and second electrode patterns 110 and 112 can vary in accordance with the amounts of voltages to be applied to the first and second electrode patterns 110 and 112. In one example embodiment, the first and second electrode patterns 110 and 112 can have thicknesses of about 10 nm to about 500 nm.

Opposite sidewalls of the first and second electrode patterns 110 and 112 can have substantially the same areas. The first and second electrode patterns 110 and 112 can include the same conductive material. Alternatively, the first and second electrode patterns 110 and 112 can include different conductive materials.

Particularly, the first and second electrode patterns 110 and 112 can include metal, metal silicide, polysilicon doped with impurities, as examples. These can be used alone or in a combination.

An insulating layer pattern 104 making contact with rear faces of the first and second electrode patterns 110 and 112 can be provided on the supporting substrate 100. The insulating layer pattern 104 need not be provided between opposing (or opposite) sidewalls of the first and second electrode patterns 110 and 112. Thus, an opening 116 between the opposite sidewalls of the first and second electrode patterns 110 and 112 can be defined, backed by a portion of the insulating layer patter 104.

The insulating layer pattern 104 can include silicon oxide, for example. Particularly, the insulating layer pattern 104 can include tetra-ethyl-ortho-silicate (TEOS), undoped silicate glass (USG), spin-on-glass (SOG), high-density plasma chemical vapor deposition (HDP-CVD) oxide, and so on, as examples. An upper face of the insulating layer pattern 104 and the upper faces of the first and second electrode patterns 110 and 112 are substantially coplanar.

A third electrode pattern 132 can be formed on the insulating layer pattern 104. The third electrode pattern 132 can include a first portion A supported by the insulating layer pattern 104 and a second portion B extending beyond the insulting layer pattern 104 and over portions of upper faces of the first and second electrode patterns 110 and 112. The third electrode pattern 132 can be spaced apart from the upper faces of the first and second electrode patterns 110 and 112 by a first distance. The third electrode pattern 132 can include a metal having a relatively small resistance. The third electrode pattern 132 can be formed using one conductive material. Alternatively, the third electrode pattern 132 can be formed using at least two conductive materials.

Particularly, the third electrode pattern 132, supported by the insulating layer pattern 104, can have a linear shaped portion extending over the opening 116, i.e., portion B. The first portion A of the third electrode pattern 132 located on the insulating layer pattern 104 can have a first thickness. The second portion B of the third electrode pattern 132 located over the opening 116 and between the first and second electrode patterns 110 and 112 can have a second thickness smaller than the first thickness. That is, the second portion B of the third electrode pattern 132 extending over an edge of the insulating layer pattern 104 can have the second thickness such that the first and second electrode patterns 110 and 112 are not electrically connected to each other. The upper face of the third electrode pattern 132 can be relatively flat.

A fourth electrode pattern 136 can extend from a bottom face of portion B of the third electrode pattern 132 and inside of the opening 116. The fourth electrode pattern 136 can be spaced apart from the first electrode pattern 110, the second electrode pattern 112, the insulating layer pattern 104, and the supporting substrate 100. The fourth electrode pattern 136 can include a conductive material having an elasticity depending on a potential difference. An end portion of the fourth electrode pattern 136 disposed toward the supporting substrate 100 can have a rounded shape. That is, the end portion of the fourth electrode pattern 136 can have a convex circle shape, in the present embodiment. The end portion of the fourth electrode pattern 136 can be spaced apart from the sidewalls of the first and second electrode patterns 110 and 112.

The fourth electrode pattern 136 can make contact with one of the first electrode pattern 110 or the second electrode pattern 112 in response to a potential difference between the fourth electrode pattern 136 and at least one of the first and second electrode patterns 110 and 112. Thus, the fourth electrode pattern 136 can include a conductive material. For example, the conductive material can include a metal such as titanium, aluminum, as examples. These can be used alone or in a combination. The third electrode pattern 132 and the fourth electrode pattern 136 can include substantially the same conductive material.

A distance between the fourth electrode pattern 136 and the first electrode pattern 110 is hereinafter referred to as a second distance. A distance between the fourth electrode pattern 136 and the second electrode pattern 120 is hereinafter defined as a third distance. A distance between the fourth electrode pattern 136 and the insulating layer pattern 104 is hereinafter defined as a fourth distance. Particularly, the second distance can be measured between the first electrode pattern 110 and the end portion of the fourth electrode pattern 136. The third distance can be measured between the second electrode pattern 120 and the end portion of the fourth electrode pattern 136.

The non-volatile memory device can read data according to whether the fourth electrode pattern 136 makes contact with the first electrode pattern 110 or with the second electrode pattern 112. Therefore, in the non-volatile memory device, the second distance can be substantially the same as the third distance until the non-volatile memory device initially operates so that the data is not biased to a predetermined electrode pattern in an initial state.

When the second distance and the third distance are less than about 3 nm, the fourth electrode pattern 136 can move toward the first electrode pattern 110 or the second electrode pattern 112 by a relatively small potential difference. Thus, the data can be easily changed by external noise. Alternatively, when the second distance and the third distance are more than about 20 nm, a moving distance of the fourth electrode pattern 136 increases so that the fourth electrode pattern 136 can be easily damaged by continuously performed writing operations. Thus, the second distance and the third distance can be in a range of about 3 nm to about 20 nm. Alternatively, the second distance and the third distance can be variably changed according to the width and thickness of the fourth electrode pattern 136 and the rounded shape of the edge portion of the fourth electrode pattern 136.

As described above, the fourth electrode pattern 136 recording the data by the electromechanical operation is spaced apart from the supporting substrate 100 so that the fourth electrode pattern 136 can easily move toward the first and second electrode patterns 110 and 112 in response to the potential difference between the fourth electrode pattern 136 and at least one of the first and second electrode patterns 110 and 112. For example, in this embodiment, the fourth electrode pattern 136 is a downwardly protruded structure having a rounded end portion, having convex sidewalls, so that the fourth electrode pattern 136 can move toward the first electrode pattern 110 or the second electrode pattern 112 by the small potential difference easier than a fourth electrode pattern having a non-rounded end portion.

In addition, the third electrode pattern 132 is not shifted by the potential difference in a writing operation or a reading operation so that the electromechanical non-volatile memory device can operate stably compared with the conventional electromechanical non-volatile memory device.

According to an example embodiment, the electromechanical non-volatile memory device can have an improved operation characteristic and a relatively high reliability. For example, when the fourth electrode pattern 136 has the rounded end portion having the convex sidewalls, the fourth electrode pattern 136 moves easily by the small potential difference so that the power consumption of the memory device can be reduced.

Hereinafter, an operation of the electromechanical non-volatile memory device in FIG. 1 will be illustrated.

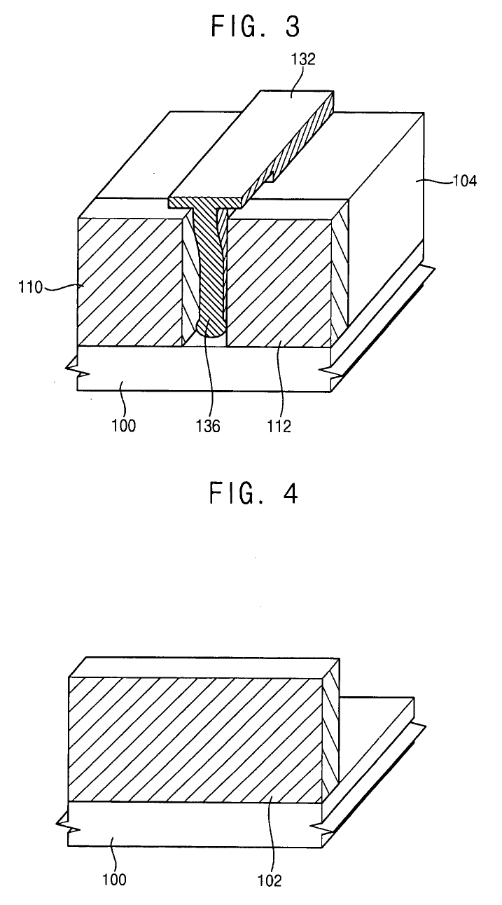

FIGS. 2 and 3 are cross-sectional views illustrating data storage states of the electromechanical non-volatile memory device in FIG. 1.

Referring to FIGS. 2 and 3, when the fourth electrode pattern 136 makes contact with the first electrode pattern 110, a “0” state can be defined. A “1” state can be defined when the fourth electrode pattern 136 does not make contact with the first electrode pattern 110. For example, the “1” state can be also defined when the fourth electrode pattern 136 makes contact with the second electrode pattern 112, as illustrated in FIG. 3, and when the fourth electrode pattern 136 does not make contact with either of the first and second electrode patterns 110 and 112, as illustrated in FIG. 1.

Firstly, the fourth electrode pattern 136 moves by the potential difference between the first electrode pattern 110 and the third electrode pattern 132. Thus, data “1” or data “0” is recorded in the non-volatile memory device.

For example, when a writing voltage for recording the data “0” is applied to both end portions of the third electrode pattern 132 and the first electrode pattern 110, the fourth electrode pattern 136 makes contact with the first electrode pattern 110 so that the data “0” can be recorded. In addition, when a writing voltage for recording the data “1” is applied to the both end portions of the third electrode pattern 132 and the first electrode pattern 110, the fourth electrode pattern 136 is separated from the first electrode pattern 110 so that the data “1” can be recorded. Although the voltage is not applied after the writing operation, a contact state of the fourth electrode pattern 136 is not changed so that the recorded data is not changed.

To read the data recorded in the electromechanical non-volatile memory device, a reading voltage can be applied to both end portions of the third electrode pattern 132 and the second electrode pattern 112.

When the data “0” is recorded in the electromechanical non-volatile memory device, the fourth electrode pattern 136 makes contact with the first electrode pattern 110 so that the fourth electrode pattern 136 does not move toward the second electrode pattern 112, even though the writing voltage is applied. Thus, the third electrode pattern 132 and the second electrode pattern 112 are opened so that a current cannot flow between the third electrode pattern 132 and the second electrode pattern 112.

For example, when the data “1” is recorded in the electromechanical non-volatile memory device, the fourth electrode pattern 136 can make contact with the second electrode pattern 112 or the fourth electrode pattern 136 does not make contact with either of the first and second electrode patterns 110 and 112.

When the fourth electrode pattern 136 makes contact with the second electrode pattern 112, the reading voltage is applied to the both end portions of the third electrode pattern 132 and the second electrode pattern 112 so that the current can flow between the third electrode pattern 132 and the second electrode pattern 112.

In addition, when the fourth electrode pattern 136 does not make contact with both the first and second electrode patterns 110 and 112, the reading voltage is applied to the both end portions of the third electrode pattern 132 and the second electrode pattern 112 so that the fourth electrode pattern can make contact with the second electrode pattern 112 by the potential difference. Thus, an electric short can be generated between the third electrode pattern 132 and the second electrode pattern 112 so that the current can flow between the third electrode pattern 132 and the second electrode pattern 112.

Thus, the fourth electrode pattern 136 having the elasticity by the potential difference makes contact with the first electrode pattern 110 or the second electrode pattern 112 so that the current flowing between the third electrode pattern 132 and the second electrode pattern 112 can be changed according to each state. Thus, the data recorded in the electromechanical non-volatile memory device can be read by sensing the current flowing between the third electrode pattern 132 and the second electrode pattern 112.

As described above, the first electrode pattern 110 can be used to write the data. However, the second electrode pattern 112 can be used to read the data. Thus, usages of the first and second electrode patterns 110 and 112 that face each other are different from each other so that the data can be read and/or recorded correctly.

However, the above-mentioned operation of the memory device is an example. Thus, the memory device can be operated by various methods. For example, the current difference between the fourth electrode pattern 136 and the first electrode pattern 110 and the current difference between the fourth electrode pattern 136 and the second electrode pattern 112 can be sensed by various methods according to the movement and the contact state of the fourth electrode pattern 136.

Hereinafter, an embodiment of a method of manufacturing a electromechanical non-volatile memory device will be described.

FIGS. 4 to 15 are perspective views illustrating an embodiment of a method of manufacturing the electromechanical non-volatile memory device in FIG. 1.

Referring to FIG. 4, a supporting substrate 100 can be provided. An upper face of the supporting substrate 100 can have an upper face having an insulating property.

A first conductive layer (not shown) is formed on the supporting substrate 100. The first conductive layer is to be transformed into first and second electrode patterns. The first conductive layer is formed such that a height of the first conductive layer is substantially larger than those of the first and second electrode patterns. The first conductive layer can have a height of about 10 nm to about 500 nm. However, the heights of the first and second electrode patterns can vary in accordance with a level of voltage applied to the first and second electrode patterns so that the height of the first conductive layer need not be construed as limits to the above example. A conductive material used to form the first conductive layer can be polysilicon doped with impurities, metal silicide, metal, and so on, as examples. These can be used alone or in a combination.

The first conductive layer is then patterned to form a preliminary electrode pattern 102 on the supporting substrate 100.

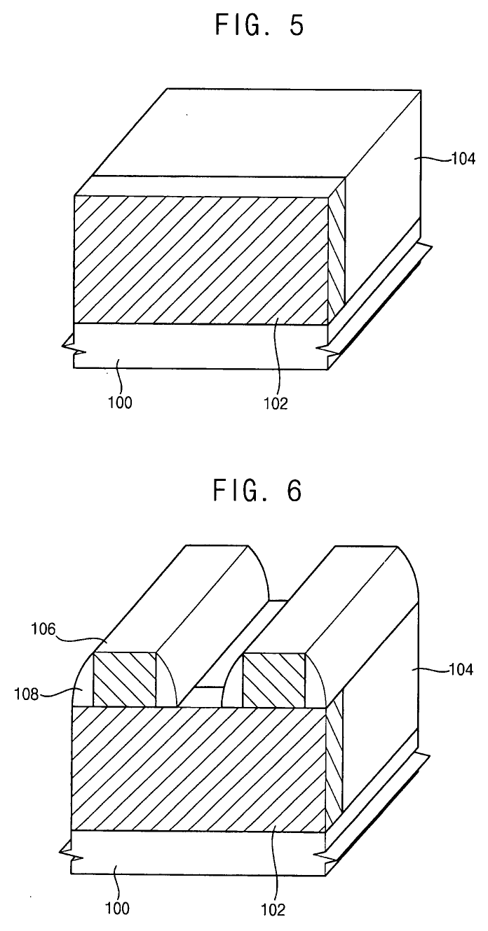

Referring to FIG. 5, an insulating layer (not shown) can be formed on the supporting substrate 100 to cover the preliminary electrode pattern 102. The insulating layer can be planarized until an upper face of the preliminary electrode pattern 102 is exposed. For example, the insulating layer can be planarized by a chemical mechanical polishing (CMP) process. Thus, an insulating layer pattern 104 making contact with a rear face of the preliminary electrode pattern 102 can be formed on the supporting substrate 100.

Referring to FIG. 6, a first hard mask layer (not shown) can be formed on the insulating layer pattern 104. The first hard mask layer can be formed using a material that is hardly etched when a dry etching process is performed to the insulating layer pattern 104.

The first hard mask layer is then patterned into a first hard mask pattern 106 covering regions of the preliminary electrode pattern 102 from which the first and second electrode patterns are to be formed. The first hard mask layer can be patterned into the first hard mask pattern 106 by a photolithography process.

A layer to be transformed into a spacer 108 can be formed to cover the first hard mask pattern 106, the preliminary electrode pattern 102, and the insulating layer pattern 104. Thereafter, the layer can be anisotropically etched to form the spacer 108 on a sidewall of the first hard mask pattern 106. Thus, a width of an exposed portion of the preliminary electrode pattern 102 can be reduced by the spacer 108. As a result, a width between the first and second electrode patterns subsequently formed by etching the preliminary electrode pattern 102 can also decrease.

However, when a desired width of the first hard mask pattern 106 can be obtained by performing only the photolithography process, processes for forming the spacer 108 can be omitted.

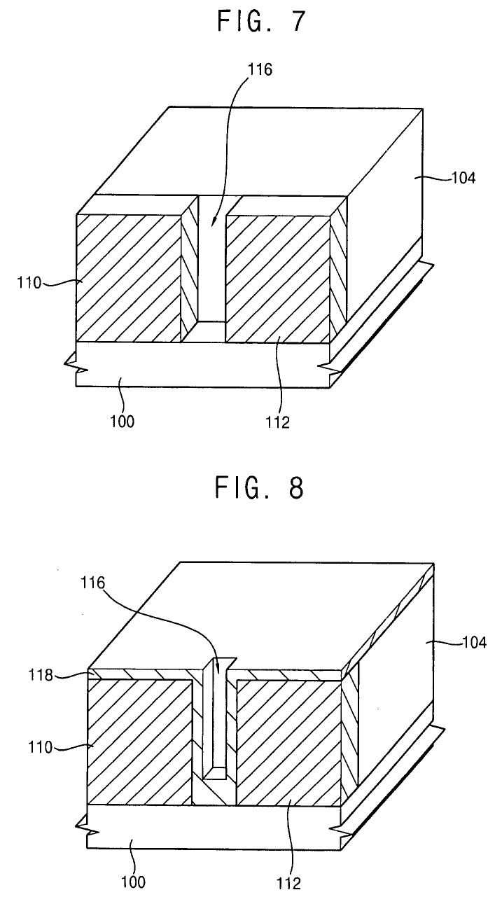

Referring to FIG. 7, the preliminary electrode pattern 102 can be etched by an etching process employing the first hard mask pattern 106 and the spacer 108 as an etching mask. Thus, the first and second electrode patterns 110 and 112 facing each other can be formed on the supporting substrate 100. Opposite sidewalls of the first and second electrode patterns 110 and 112 can have the same area.

The insulating layer pattern 104 is provided on rear faces of the first and second electrode patterns 110 and 112 formed by etching the preliminary electrode pattern 102 so that the isolated first opening 116 can be defined. Particularly, the first opening 116 can be defined by the insulating layer pattern 104, the first electrode pattern 110, and the second electrode pattern 112.

The first hard mask pattern 106 and the spacer 108 can be then removed.

Referring to FIG. 8, a sacrificial layer 118 is formed on the first electrode pattern 110, the second electrode pattern 112, the supporting substrate 100, and the insulating layer pattern 104. The sacrificial layer 118 can be formed using a material having an etching selectively with respect to the first and second electrode patterns 110 and 112. In addition, the sacrificial layer 118 can be formed using a material having an etching selectively with respect to third and fourth electrode patterns formed by subsequent processes. For example, the sacrificial layer 118 can be formed using a material, such as amorphous silicon, silicon germanium, germanium, and so on.

The sacrificial layer 118 can partially fill the first opening 116 such that the sacrificial layer 118 can conform to the opposite surfaces of the first and second electrode patterns 110 and 112. Thus, a second opening 117 can be defined by the sacrificial layer 118. The sacrificial layer 118 can have a thickness smaller than half of an inner width of the opening 116. A portion of the sacrificial layer 118 located on the supporting substrate 100 can have a relatively thick thickness because an end portion of the fourth electrode pattern is formed inside the portion of the sacrificial layer 118 located on the bottom face of the first opening 116. The relatively thick thickness can be obtained by controlling conditions of processes required for forming the sacrificial layer 118.

In addition, a lateral thickness of the sacrificial layer can be substantially the same as the second distance between the first electrode pattern and the fourth electrode pattern that is subsequently formed in the second opening 117. The lateral thickness of the sacrificial layer can also be substantially the same as the third distance between the fourth electrode pattern and the second electrode pattern. An inner width of the second opening 117 defined by the sacrificial layer 118 is substantially the same as a width of the fourth electrode pattern.

The second distance, the third distance, and the width of the fourth electrode pattern can be adjusted by controlling the thickness of the sacrificial layer 118.

As illustrated in FIG. 1, the second and third distances can be about 3 nm to about 20 nm. Thus, the sacrificial layer 118 can be preferably formed to have a thickness of about 3 nm to about 20 nm. However, the thickness of the sacrificial layer 118 can be changed in accordance with the width of the fourth electrode pattern and the rounded end portion of the fourth electrode pattern.

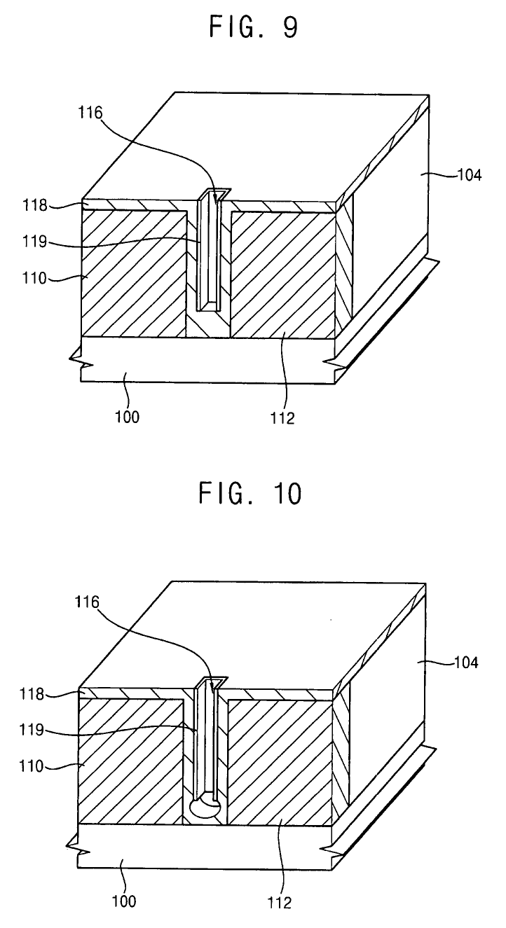

Referring to FIG. 9, an etch stop layer 119 is formed selectively on a portion of the sacrificial layer 118 formed on sidewalls of the second opening 117. For example, the etch stop layer 119 can be formed using a material having an etching selectivity with respect to the sacrificial layer 118. For example, the material can be silicon nitride. The etch stop layer 119 can be formed by a deposition process and an etch-back process.

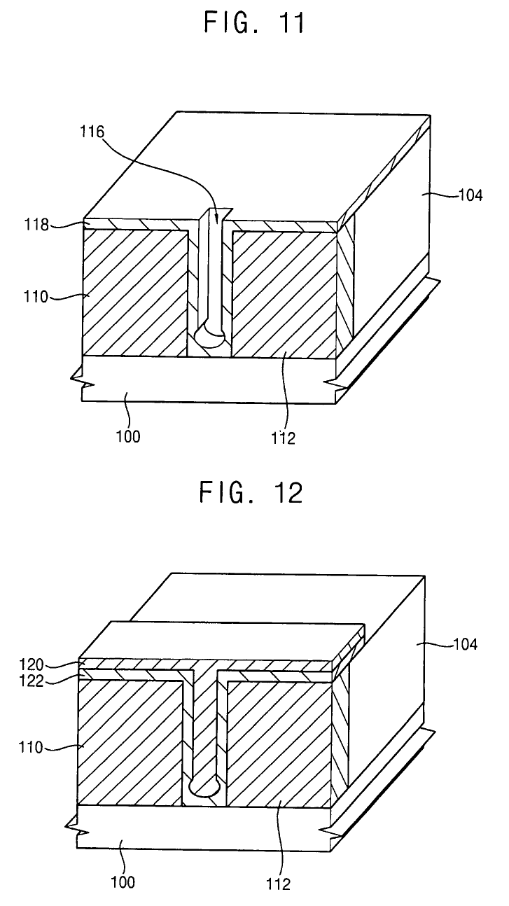

Referring to FIGS. 10 and 11, the portion of the sacrificial layer 118 formed on the supporting substrate 100 is selectively etched after the etch stop layer 119 is formed. The portion of the sacrificial layer 119 can be etched by an isotropic etching process. Thus, a bottom face of the second opening 117 can be formed to have a rounded shape having concave sidewalls.

Processes required for allowing the bottom face of the second opening 117 to have the rounded shape can be performed after the sacrificial layer 119 is formed. Particularly, the etch stop layer 119 is formed on a sidewall of the sacrificial layer 118. The bottom face of the second opening 117 is then etched such that the bottom face of the second opening 117 can have the rounded shape having the concave side portion.

The etch stop layer 119 is then removed. The sacrificial layer 118 need not removed when the etch stop layer 119 is removed, so that the sacrificial layer 118 is not substantially affected by removing the etch stop layer 119.

Referring to FIG. 12, a second hard mask layer (not shown) can be formed on the sacrificial layer 118. The second hard mask layer can be formed to fill up the second opening 117 defined by the sacrificial layer 118.

The second hard mask layer is then patterned into a second hard mask pattern 120 by a photolithography process. The second hard mask pattern 120 can be provided on the first electrode pattern 110 and the second electrode pattern 112 to fill up the opening 117. The second hard mask pattern 120 can be provided to cover an edge portion of the insulating layer 104 adjacent to the first and second electrode patterns 110 and 112.

The sacrificial layer 118 is etched using the second hard mask pattern 120 as an etching mask so that a preliminary sacrificial layer pattern 122 can be formed. As with sacrificial pattern 118, the preliminary sacrificial layer pattern 122 is provided on the first electrode pattern 110 and the second electrode pattern 112, and fills up opening 116 to form the second opening 117.

Although not particularly illustrated in the drawings, the second hard mask pattern 120 can be removed after the preliminary sacrificial layer pattern 122 is formed, as will be appreciated by those skilled in the art.

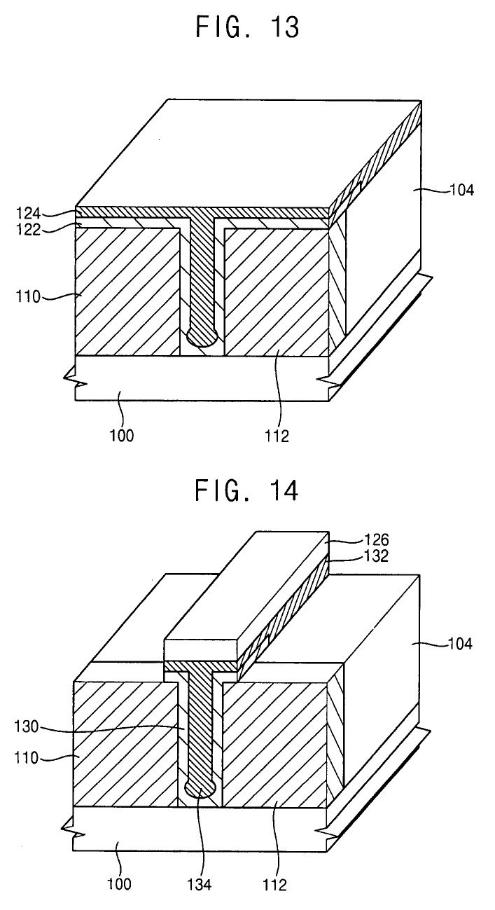

Referring to FIG. 13, a second conductive layer 124 is formed on the preliminary sacrificial layer pattern 122 and the insulating layer pattern 104 to fill up the second opening 117. The second conductive layer 124 can be transformed into the third and fourth electrode patterns by subsequent processes.

The second conductive layer 124 can be formed by depositing a conductive material having an elasticity in accordance with a potential difference. For example, the second conductive layer 124 can be formed using a metal having a relatively low resistance. Particularly, the metal can be titanium, aluminum, and so on, as examples. These can be used alone or in a combination.

Alternately, the second opening 117 can be partially filled with a first conductive material having an elasticity depending on the potential difference. The second opening 117 can then be filled with a second conductive material having a substantially lower resistance than the first conductive material. Thus, the second conductive layer 124 can be formed.

Referring to FIG. 14, a third hard mask pattern 126 is formed on the second conductive layer 124. The third hard mask pattern 126 can be formed over the second opening 117 and a portion of the insulating layer pattern 104 adjacent to the second opening 117.

The second conductive layer 124 and the preliminary sacrificial layer pattern 122 can be etched using the third hard mask pattern 126 as an etching mask. The third electrode pattern 132 and a preliminary fourth electrode pattern 134 are formed by the etching process. For example, the third electrode pattern 132 supported by the insulating layer pattern 104 can extend such that the third electrode pattern 132 is spaced apart from upper faces of the first and second electrode patterns 110 and 112 by the first distance. For example, the preliminary fourth electrode pattern 134 can extend from a bottom face of the third electrode pattern 132 to fill the second opening 117. In addition, the preliminary sacrificial layer pattern 122 can be transformed into a sacrificial layer pattern 130 by the etching process.

The sacrificial layer pattern 130 is formed to cover an upper face end portion of the insulating layer pattern 104 adjacent to the first and second electrode patterns 110 and 112 so that a bottom portion of the third electrode pattern 132 adjacent to the edge portion of the insulating layer pattern 104 does not make contact with the first and second electrode patterns 110 and 112.

Although not particularly illustrated in the drawings, the third hard mask pattern 126 can be then removed, as will be appreciated by those skilled in the art.

Referring to FIG. 15, the sacrificial layer pattern 130 exposed under the third electrode pattern 132 can be removed by an isotropic etching process. The isotropic etching process can be a wet etching process. Thus, the fourth electrode pattern 136 spaced apart from the first electrode pattern 110, the second electrode pattern 112, the insulating layer pattern 104, and the supporting substrate 100 can be formed. The fourth electrode pattern 136 can have a rounded end portion. Particularly, sidewalls of the rounded end portion can be convex.

The above processes are subsequently performed so that the electromechanical non-volatile memory device in FIG. 1 can be manufactured.

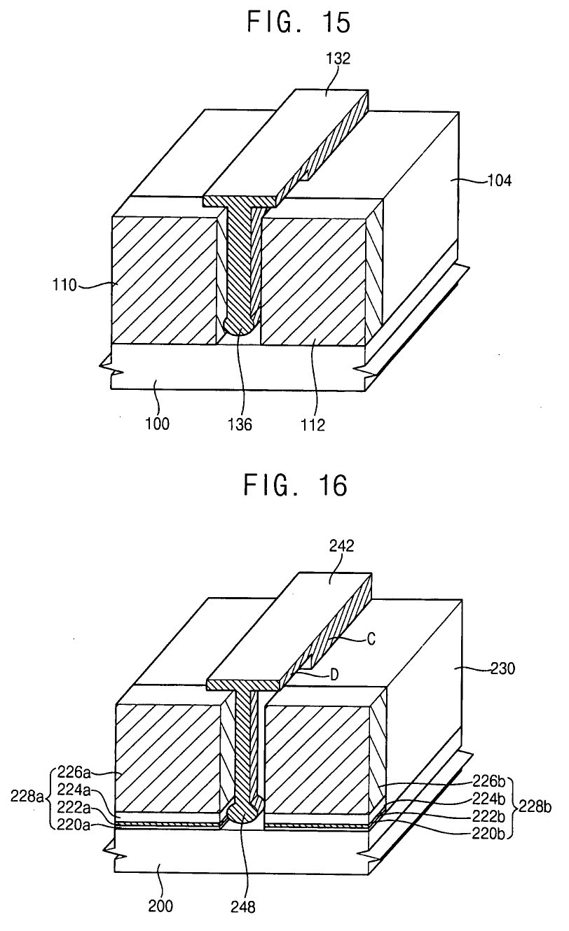

FIG. 16 is a perspective view illustrating another embodiment of an electromechanical non-volatile memory device in accordance with an aspect of the present invention.

The electromechanical non-volatile memory device in FIG. 16 is substantially the same as the electromechanical non-volatile memory device in FIG. 1 except for an insulating layer pattern, an electric charge trapping layer pattern, and a dielectric layer pattern that are used to store the electric charge formed between the first electrode pattern and the substrate and between the second electrode pattern and the substrate. Thus, the same reference numerals will be used to refer to the same or like parts as those described in FIG. 1 and any further explanations of common elements will be omitted.

Referring to FIG. 16, a supporting substrate 200 including an upper face having an insulating property can be provided.

A first insulating layer pattern 220a, a first electric charge trapping layer pattern 222a, and a first dielectric layer pattern 224a are formed on the supporting substrate 200. In addition, a first electrode pattern 226a is formed on the first dielectric layer pattern 224a.

A second insulating layer pattern 220b, a second electric charge trapping layer pattern 222b, and a second dielectric layer pattern 224b are formed on the supporting substrate 200 to substantially face the first electrode pattern 226a. In addition, a second electrode pattern 226b is formed on the second dielectric layer pattern 224b.

Hereinafter, a structure including the first insulating layer pattern 220a, the first electric charge trapping layer pattern 222a, the first dielectric layer pattern 224a, and the first electrode pattern 226a is referred to as a first electrode structure 228a. A structure including the second insulating layer pattern 220b, the second electric charge trapping layer pattern 222b, the second dielectric layer pattern 224b, and the second electrode pattern 226b is referred to as a second electrode structure 228b.

An insulating layer pattern 230 making contact with rear faces of the first and second electrode structures 228a and 228b can be provided. A third electrode pattern 242 can be supported on the insulating layer pattern 230. The third electrode pattern 242 can include a first portion C supported by the insulating layer pattern 230 and a second portion D extending beyond the insulting layer pattern 230 and over portions of upper faces of the first and second electrode patterns 226a and 26b. The third electrode pattern 242 can be spaced apart from upper faces of the first and second electrode patterns 226a and 226b by a first distance. A fourth electrode pattern 248 can extend from a bottom face of the second portion D of the third electrode pattern 242 and inside of a second opening 233. The fourth electrode pattern 248 can be spaced apart from sidewalls of the first electrode pattern 226a, the second electrode pattern 226b, an insulating interlayer 230, and the supporting substrate 200. The fourth electrode pattern 248 can include a conductive material having an elasticity depending on a potential difference. The fourth electrode pattern 248 can have a rounded end portion disposed toward the supporting substrate 200. The rounded end portion can have convex sidewalls, in this embodiment.

The electric charges can be stored in at least one of the first and second electric trapping layer patterns 222a and 222b. In addition, when the memory device operates, the electric charges can not be removed from the trapping layer.

The rounded end portion of the fourth electrode pattern 248 can be disposed proximate to the first dielectric layer pattern 224a of the first electrode structure 228a and the second dielectric layer pattern 224b of the second electrode structure 228b. When the rounded end portion of the fourth electrode pattern 248 makes contact with the first electric charge trapping layer pattern 222a of the first electrode structure 228a or the second electric charge trapping layer pattern 222b of the second electrode structure 228b, the electric charges can be removed from the first electric charge trapping layer pattern 222a or the second electric charge trapping layer pattern 222b.

When the fourth electrode pattern 248 makes contact with one of the first and second electrode patterns 226a and 226b, the electric charges stored in the trapping layer pattern can allow the fourth electrode pattern 248 to keep in contact with one of the first and second electrode patterns 226a and 226b.

One of the first and second electrode patterns 226a and 226b can be used as an electrode pattern for writing data. The other of the first and second electrode patterns 226a and 226b can be used as an electrode pattern for reading the data. The electric charges can be stored in the electric charge trapping layer formed under the electrode pattern for writing the data.

When the first electrode pattern 226a is used as the electrode pattern for writing data, the electric charge can be stored in the first electric charge trapping layer pattern 222a. When the fourth electrode pattern 248 makes contact with the first electrode pattern 226a to perform a writing operation, the contact between the fourth electrode pattern 248 and the first electrode pattern 226a can be maintained by the electric charge. Thus, data retention of the non-volatile memory device can be largely improved.

As a result, the fourth electrode pattern can stably make contact with the first electrode pattern or the second electrode pattern by the electric charge stored in the first and second electric charge trapping layers. A position of the fourth electrode pattern can allow the fourth electrode pattern to make contact with the first dielectric layer pattern and the second dielectric layer pattern. In this case, operation characteristics of the electromechanical non-volatile memory device can be improved.

Hereinafter, an embodiment of a method of manufacturing the above the electromechanical non-volatile memory device will be illustrated.

FIGS. 17 to 23 are perspective views illustrating a method of manufacturing the electromechanical non-volatile memory device in FIG. 16.

The method in FIGS. 17 to 23 can be substantially the same as the method in FIGS. 4 to 15 except for forming an oxide layer pattern, an electric charge trapping layer pattern, and a dielectric layer pattern on the substrate.

Referring to FIG. 17, a supporting substrate 200 including an upper face having an insulating property can be provided.

An oxide layer (not shown), an electric charge trapping layer (not shown) and a dielectric layer (not shown) can be formed on the supporting substrate 200. The oxide layer can be formed by depositing silicon oxide. The electric charge trapping layer can be formed by depositing silicon nitride. The dielectric layer can be formed by depositing silicon oxide.

A first conductive layer (not shown) can be formed on the dielectric layer, to ultimately form the first and second electrode patterns. The first conductive layer can be formed such that the first conductive layer can be thicker than the first and second electrode patterns.

A preliminary oxide layer pattern 202, a preliminary electric charge trapping layer pattern 204, a preliminary dielectric layer pattern 206, and a preliminary electrode pattern 208 can be formed by patterning the first conductive layer, the dielectric layer, the electric charge trapping layer, and the oxide layer. The preliminary oxide layer pattern 202, the preliminary electric charge trapping layer pattern 204, the preliminary dielectric layer pattern 206, and the preliminary electrode pattern 208 can have substantial linear shapes.

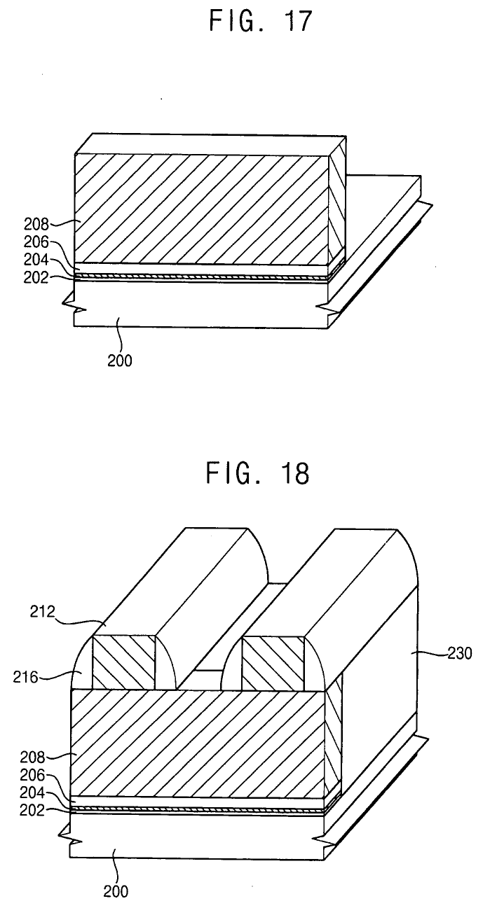

Referring to FIG. 18, an insulating layer pattern 230 making contact with rear faces of the preliminary electrode pattern 208 can be formed on the supporting substrate 200. A first hard mask pattern 212 and a spacer 216 used as masks for forming the first and second electrode patterns can be formed on the insulating layer pattern 230.

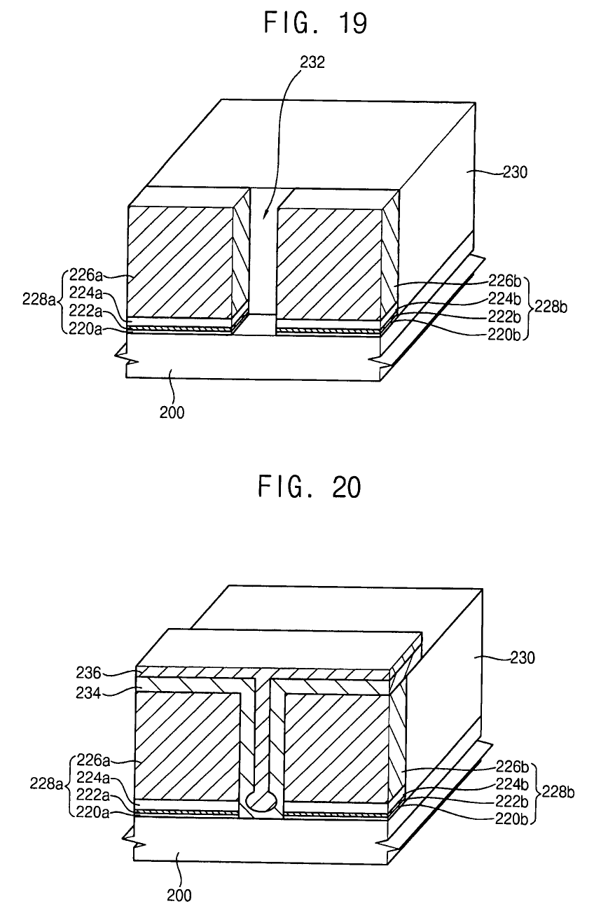

Referring to FIG. 19, the preliminary electrode pattern 208, the preliminary dielectric layer pattern 206, the preliminary electric charge trapping layer pattern 204, and the preliminary oxide layer pattern 202 can be subsequently etched using the first hard mask pattern 212 and the spacer 216 as an etching mask. Thus, a first electrode structure 228a including a first oxide layer pattern 220a, a first electric charge trapping layer pattern 222a, a first dielectric layer pattern 224a, and a first electrode pattern 220a can be formed. And a second electrode structure 228b including a second oxide layer pattern 220b, a second electric charge trapping layer pattern 222b, a second dielectric layer pattern 224b, and a second electrode pattern 220b can be formed. The second electrode structure 228b can face the first electrode structure 228a. Opposite sidewalls of the first and second electrode patterns 226a and 226b can have substantially the same size.

The insulating layer pattern 230 is formed on rear faces of the first and second electrode patterns 226a and 226b by the etching, process so that a first opening 232 having an isolated shape can be formed between the first and second electrode patterns 226a and 226b, and backed by the insulating layer pattern 230.

Thereafter, the first hard mask pattern 212 and the spacer 216 can be removed.

Referring to FIG. 20, a sacrificial layer (not shown) can be formed on surfaces of the first electrode structure 228a, the second electrode structure 228b, the supporting substrate 200, and the insulating layer pattern 230. The sacrificial layer filling the first opening 232 can be conformed to the first and second electrode patterns 228a and 228b. Thereafter, a second opening 233 can be defined by the sacrificial layer.

Particularly, a second hard mask layer (not shown) can be formed on the sacrificial layer. The second hard mask layer is patterned by a photolithography process so that a second hard mask pattern 236 covering the first electrode structure 228a, the second electrode structure 228b and an inner face of the first opening 232 can be formed on the sacrificial layer.

The sacrificial layer is etched using the second hard mask pattern 236 as the etching mask so that a preliminary sacrificial layer pattern 234 covering the first electrode structure 228a, the second electrode structure 228b, and the inner face of the first opening 232 can be formed.

Although not particularly illustrated in the drawings, the second hard mask pattern 236 can be removed, as will be appreciated by those skilled in the art.

Processes substantially the same as those illustrated in FIGS. 9 to 11 are performed so that a bottom face of a second opening 233 can be formed to have a concave shape. The bottom face having the rounded shape can be formed before the second hard mask layer pattern is formed. Alternatively, the bottom face having the rounded shape can be formed after the second hard mask layer pattern is formed. The bottom face of the second opening 233 can horizontally correspond to the first dielectric layer pattern 224a of the first electrode structure 228a and the second dielectric layer pattern 224b of the second electrode structure 228b.

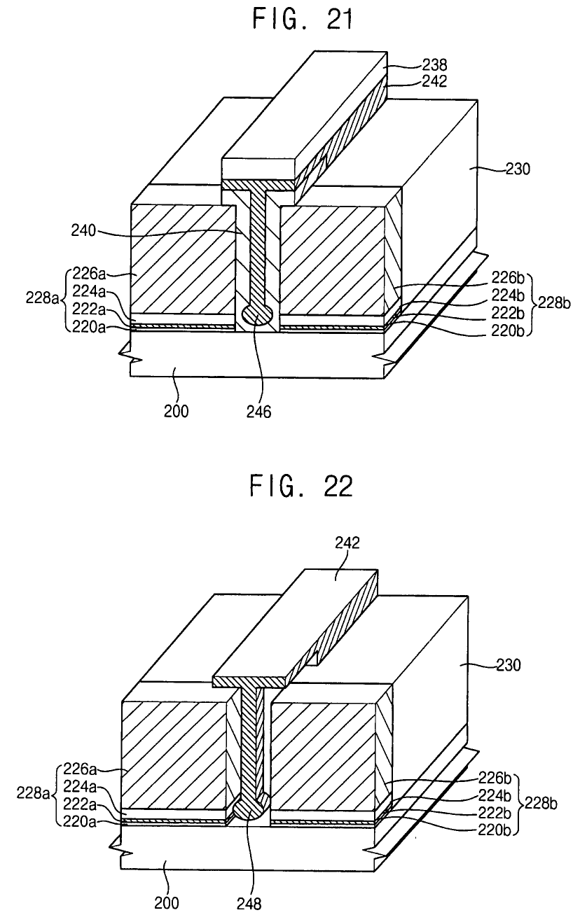

Referring to FIG. 21, a second conductive layer (not shown) can be formed on the preliminary sacrificial layer pattern 234 and the insulating layer pattern 230 to fill up the second opening 233. The second conductive layer can be provided as a third electrode pattern and a fourth electrode pattern by a subsequent process. Processes for forming the second conductive layer can be substantially the same as the processes in FIG. 13.

A third hard mask pattern 238 is formed on the second conductive layer. The third hard mask pattern 238 can cover the second opening 233 and a portion of the insulating layer pattern 230 adjacent to the second opening 233.

The second conductive layer and the preliminary sacrificial layer pattern 234 can be etched using the third hard mask pattern 238 as the etching mask. Thus, the third electrode pattern 242 and the preliminary fourth electrode pattern 246 can be formed by the etching process. The third electrode pattern 242 can be supported on the insulating layer patterns 230. The third electrode pattern 242 can extend to be spaced apart from the upper face of the first and second electrode patterns 226a and 226b by a first distance. The preliminary fourth electrode pattern 242 can extend from the bottom face of the third electrode pattern 242 to inside of the second opening 233. In addition, the preliminary sacrificial layer pattern 234 can be transformed into a sacrificial layer pattern 240.

Referring to FIG. 22, exposed sidewalls of the sacrificial layer pattern 240 are removed by an isotropic etching process so that the fourth electrode pattern 248 is formed. The fourth electrode pattern 248 can be spaced apart from the first electrode pattern 226a, the second electrode pattern 226b, the substrate 200, and the insulating layer pattern 230. The fourth electrode pattern 248 can have a shape extending to the inside of the second opening 233.

The third hard mask pattern can be mostly removed by the etching process. The remains of the third hard mask pattern can be removed as illustrated in the drawings.

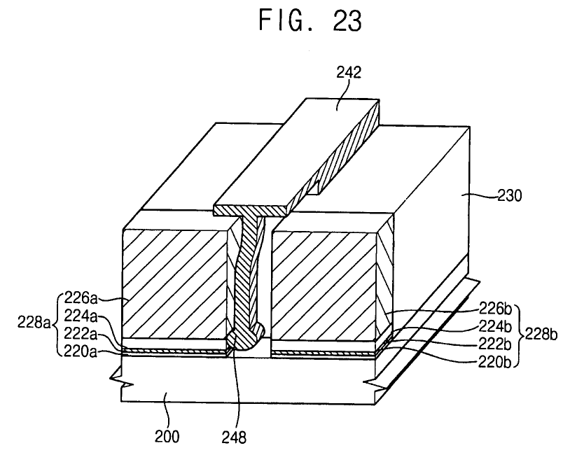

Referring to FIG. 23, a potential difference between the first electrode pattern 226a and the third electrode pattern 242 is adjusted so that the third electrode pattern 242 can make contact with the first electrode pattern 226a or the second electrode pattern 226b. Alternatively, the third electrode pattern 242 can make contact with the first electrode pattern 226a used as the electrode pattern for writing data.

Voltage is applied to the third electrode pattern 242 so that the electric charges can be injected into the first electric charge trapping layer pattern 222a of the first electrode structure 228a.

When the electric charge is sufficiently injected into the first electric charge trapping layer pattern 222a, the potential difference between the first electrode pattern 226a and the third electrode pattern 242 is adjusted so that the fourth electrode pattern 248 can become spaced apart from the first electrode pattern 226a.

As described above, the electric charge can be injected only into the first electric charge trapping layer pattern 222a formed under the first electrode pattern 226a used as the electrode pattern for writing data. However, the first and second electrode patterns 226a and 226b can be operated without causing differences between the electrode pattern for writing data and the electrode pattern for reading data. In this case, the electric charge can be injected into both of the first and second electric charge trapping layer patterns 222a and 222b by substantially the same process.

The electromechanical non-volatile memory device can be manufactured by the above processes.

The electromechanical non-volatile memory device can be formed on the flat supporting substrate including the insulating material instead of a silicon substrate. Thus, semiconductor circuits including transistors can be formed on the silicon substrate, and the electromechanical non-volatile memory device can be formed on an insulating interlayer covering the transistors. At least two semiconductor devices having different characteristics can be formed on one substrate.

According to aspects of the present invention, data are recorded by the fourth electrode pattern spaced apart from the supporting substrate and moving in the right and left directions so that operation characteristic of the electromechanical non-volatile memory device can be satisfactorily achieved. In addition, the third electrode pattern connected to the fourth electrode pattern need not be shifted by the potential difference in a writing operation and/or a reading operation so that the operation of the electromechanical non-volatile memory device can be stably performed.

In addition, the oxide layer pattern, the electric charge trapping layer pattern, and the dielectric layer pattern can be formed between the first electrode pattern and the supporting substrate or between the second electrode pattern and the supporting substrate so that a data retention of the electromechanical non-volatile memory device can be improved.

Furthermore, the fourth electrode pattern of the electromechanical non-volatile memory device can include a rounded end portion having convex sidewalls. Thus, the fourth electrode pattern can be easily shifted toward the first electrode pattern or the second electrode pattern by relatively small force, such as a potential difference. Therefore, the electromechanical non-volatile memory device can be operated by a relatively small voltage so that a power consumption of the electromechanical non-volatile memory device can be reduced.

The foregoing is illustrative of aspects of the present invention and is not to be construed as limiting thereof. Although a few embodiments have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of aspects of the present invention, which is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. An electromechanical non-volatile memory device comprising:
a supporting substrate including an upper face having an insulating property;
first and second electrode patterns formed on the supporting substrate, the first and second electrode patterns having opposing faces;
an insulating layer pattern formed on the supporting substrate, the insulating layer pattern making contact with rear faces of the first and second electrode patterns, the insulating layer pattern and the first and second electrode patterns forming an opening between the first and second electrode patterns;
a third electrode pattern formed on the insulating layer pattern, the third electrode pattern supported on the insulating layer pattern, the third electrode pattern having a portion extending to be spaced apart from upper faces of the first and second electrode patterns; and
a fourth electrode pattern extending from a bottom face of the extending portion of the third electrode pattern to an inside of the opening, the fourth electrode pattern being spaced apart from the first electrode pattern, the second electrode pattern, the insulating layer, and the supporting substrate, the fourth electrode pattern including a conductive material having an elasticity depending on a potential difference, the fourth electrode pattern having a rounded end portion toward the supporting substrate, sidewalls of the rounded end portion having a convex shape.

2. The electromechanical non-volatile memory device of claim 1, wherein the first and second electrode patterns include a same conductive material.

3. The electromechanical non-volatile memory device of claim 1, wherein a portion of the third electrode pattern formed on an upper face of the insulating layer pattern has a first thickness and a portion of the third electrode pattern formed over the opening between the first and second electrodes has a second thickness thinner than the first thickness.

4. The electromechanical non-volatile memory device of claim 1, further comprising a structure including an oxide layer pattern, an electric charge trapping layer pattern in which an electric charge is trapped, and a dielectric layer pattern, the structure being located between the first electrode pattern and the supporting substrate and between the second electrode pattern and the supporting substrate.

5. The electromechanical non-volatile memory device of claim 4, wherein the rounded end portion of the fourth electrode pattern is disposed proximate to the dielectric layer pattern of the structure.

6. The electromechanical non-volatile memory device of claim 1, wherein the fourth electrode pattern includes one of a first metal material including titanium, a second metal material including aluminum, or a third metal material including the first and second metal materials.

7. The electromechanical non-volatile memory device of claim 1, wherein the third and fourth electrode patterns include a substantially same conductive material.

8. The electromechanical non-volatile memory device of claim 1, wherein the fourth electrode pattern is configured to make contact with at least one sidewall of the first and second electrode patterns in response to a potential difference between the fourth electrode pattern and at least one of the first and second electrode patterns.

9. A method of manufacturing an electromechanical non-volatile memory device comprising:
forming a preliminary electrode pattern on a supporting substrate;
forming an insulating layer pattern making contact with a rear face of the preliminary electrode pattern on the supporting substrate;
partially etching the preliminary electrode pattern to transform the preliminary electrode pattern into first and second electrode patterns having opposing faces, including forming a first opening between the first and second electrode patterns;
successively forming a preliminary sacrificial layer pattern on sidewalls of the first opening, a bottom face of the first opening, and upper faces of the first and second electrode patterns to form a second opening defined by the preliminary sacrificial layer pattern;
forming an etch stop layer on the preliminary sacrificial layer pattern formed on the sidewalls of the first opening;
forming a bottom face of the second opening to have a rounded shape by isotropically etching a portion of the preliminary sacrificial layer pattern located on the bottom face of the first opening;
removing the etch stop layer;
depositing an electrode material on the insulating layer pattern and the preliminary sacrificial layer pattern to fill up the second opening;
partially removing the electrode material and the preliminary sacrificial layer to form a third electrode pattern and a preliminary fourth electrode pattern, the third electrode pattern being supported by the insulating layer pattern, the third electrode pattern having a portion extending and being spaced apart from upper faces of the first and second electrode patterns by a first distance, the preliminary fourth electrode pattern extending from a lower face of the extending portion of the third electrode pattern to an inside of the second opening; and
removing the sacrificial layer pattern to form the fourth electrode pattern extending from the lower face of the extending portion of the third electrode pattern to an inside of the first opening, the fourth electrode pattern being spaced apart from the first electrode pattern, the second electrode pattern, the insulating layer pattern, and the supporting substrate, the fourth electrode pattern having a rounded end portion having convex sidewalls, the fourth electrode pattern including a conductive material having an elasticity depending on a potential difference.

10. The method of claim 9, further comprising forming a structure including an oxide layer pattern, an electric charge trapping layer pattern, and a dielectric layer pattern under the preliminary electrode pattern.

11. The method of claim 10, wherein the bottom face of the second opening having the rounded shape is disposed proximate to the dielectric layer pattern of the structure.

12. The method of claim 9, wherein forming the first electrode pattern and the second electrode pattern comprises:
forming a mask pattern on the preliminary electrode pattern, the mask pattern having a linear shape extending in a first direction; and
etching the preliminary electrode pattern by using the mask pattern as an etching mask.

13. The method of claim 12, further comprising forming a spacer on a sidewall of the mask pattern after the mask pattern is formed.

14. The method of claim 9, wherein the preliminary sacrificial layer pattern is formed to a thickness thinner than half of an inner width of the first opening.

15. The method of claim 9, including removing the sacrificial layer pattern by an isotropic etching process.

16. The method of claim 9, wherein the fourth electrode pattern includes one of a first metal material including titanium, a second metal material including aluminum, or a third metal material including the first and second metal materials.

17. An electromechanical non-volatile memory device comprising:
a supporting substrate including an upper face having an insulating property;
first and second electrode patterns formed on the supporting substrate, the first and second electrode patterns having opposing faces;
an insulating layer pattern formed on the supporting substrate, the insulating layer pattern making contact with rear faces of the first and second electrode patterns, the insulating layer pattern and the first and second electrode patterns forming an opening between the first and second electrode patterns;
a third electrode pattern formed on the insulating layer pattern, the third electrode pattern supported on the insulating layer pattern, the third electrode pattern having a portion extending to be spaced apart from upper faces of the first and second electrode patterns, wherein a portion of the third electrode pattern formed on an upper face of the insulating layer pattern has a first thickness and a portion of the third electrode pattern formed over the opening between the first and second electrodes has a second thickness thinner than the first thickness; and
a fourth electrode pattern extending from a bottom face of the extending portion of the third electrode pattern to an inside of the opening, the fourth electrode pattern being spaced apart from the first electrode pattern, the second electrode pattern, the insulating layer, and the supporting substrate, the fourth electrode pattern including a conductive material having an elasticity depending on a potential difference, the fourth electrode pattern having a rounded end portion toward the supporting substrate, sidewalls of the rounded end portion having a convex shape,
wherein the fourth electrode pattern is configured to make contact with at least one sidewall of the first and second electrode patterns in response to a potential difference between the fourth electrode pattern and at least one of the first and second electrode patterns.

18. The electromechanical non-volatile memory device of claim 17, further comprising a structure including an oxide layer pattern, an electric charge trapping layer pattern in which an electric charge is trapped, and a dielectric layer pattern, the structure being located between the first electrode pattern and the supporting substrate and between the second electrode pattern and the supporting substrate.
